(19) United States
(12) Patent Application Publication
(10) Pub. No.: US 2026/0344182 A1
(43) Pub. Date: Oct. 29, 2026

(54) POLARIZED ORGANIC LIGHT-EMITTING DEVICE BASED ON TWO-DIMENSIONAL ELLIPTICAL METAL NANOPILLAR LATTICE STRUCTURED ELECTRODE AND FABRICATION METHOD THEREOF

(71) Applicant: Jilin University, Changchun (CN)

(72) Inventors: Yan-Gang BI, Changchun (CN); Shi-Rong WANG, Changchun (CN); Jing FENG, Changchun (CN); Yue-Feng LIU, Changchun (CN); Ran DING, Changchun (CN); Da YIN, Changchun (CN); Mu LIN, Changchun (CN); Jia-Shuo ZHANG, Changchun (CN)

(21) Appl. No.: 19/714,844

(22) Filed: Jun. 22, 2026

Related U.S. Application Data
(63) Continuation of application No. PCT/CN2026/082464, filed on Mar. 10, 2026.

(30) Foreign Application Priority Data
Jun. 20, 2025 (CN) 202510833359.5

(51) Int. Cl. H10K 50/80; H10K 71/00

(52) U.S. Cl. CPC H10K 50/868; H10K 71/621

(57) ABSTRACT

The present disclosure belongs to the field of optoelectronic device technology, and specifically discloses a polarized organic light-emitting device based on a two-dimensional elliptical metal nanopillar lattice structured electrode and a fabrication method. The fabrication method includes the following: the substrate is ultrasonically cleaned with a cleaning agent, and then subjected to hydrophilic treatment for use; the two-dimensional elliptical metal nanopillar lattice electrode is prepared by an electron beam lithography system. The two-dimensional elliptical lattice electrode is deposited on the sample by vacuum thermal evaporation to complete the preparation of the whole device. The present disclosure adopts the above-mentioned polarized organic light-emitting device based on the two-dimensional elliptical metal nanopillar lattice structured electrode and the fabrication method thereof, the cavity mode of the OLEDs device is directly regulated by the design of the micro-nano structured metasurface, and polarization control of the OLEDs device is realized.

### TECHNICAL FIELD

The present disclosure relates to the field of optoelectronic device technology, especially to a polarized organic light-emitting device based on a two-dimensional elliptical metal nanopillar lattice structured electrode and a fabrication method thereof.

### BACKGROUND

Organic light-emitting diodes (OLEDs), as the most competitive candidates for next-generation flat-panel displays and solid-state lighting sources, usually exhibit non-polarized light emission characteristics. With the rapid development of immersive vision and optical communication technologies, the demand for polarized light emission from OLEDs is increasing rapidly. A simple strategy is to place polarizing optical elements outside the device, which can selectively transmit the required polarization components but result in about 50% energy loss. Direct polarized emission from OLEDs can greatly simplify the device architecture and eliminate the power loss caused by the use of external optical components. In addition, photons captured inside the OLEDs can be decoupled by internal optical mode control of the device, thereby greatly improving the external quantum efficiency of OLEDs.

Uniaxially oriented materials, such as organic single crystals and chiral light-emitting groups, as well as various treatment methods including mechanical friction and stretching to align light-emitting molecules uniaxially, have been applied to OLEDs to achieve intrinsic polarized emission. However, the choice of luminescent materials is limited, and the efficiency and stability of OLEDs devices cannot yet meet commercial requirements. By integrating the optical structure with the light source, effective control of photon emission from the device can be realized. Existing technology achieves high efficiency and an ultra-high polarization ratio in linearly polarized white light-emitting devices by using integrated dielectric nanogratings. Embedding photonic crystal structures into LED structures creates highly diffractive optical media and achieves high-polarization emission. Among various optical structures, artificial optical metasurfaces based on subwavelength micro- and nanostructures provide unprecedented flexibility for photon manipulation in light-emitting devices by controlling the phase, intensity, and polarization of light waves.

### SUMMARY

The purpose of the present disclosure is to provide a polarized organic light-emitting device based on a two-dimensional elliptical metal nanopillar lattice structured electrode and a fabrication method thereof. By integrating a two-dimensional elliptical metal nanopillar lattice structure with ITO, a composite electrode is designed as an OLEDs device anode. Meanwhile, the polarization control of OLEDs devices is realized, and the light extraction efficiency of OLEDs devices is improved. The cavity mode of the OLEDs device is directly regulated by the design of the micro-nano structure metasurface, so as to realize the polarized light emission of the OLEDs device in the fields of display and lighting without the external optical components of the accessory and without the limitation of the polarized light material; the two-dimensional elliptical metal nanopillar lattice structure excites the internal non-radiative mode coupling out of the device to achieve device light extraction efficiency improvement and device performance optimization.

In order to achieve the above purposes, the present disclosure provides a fabrication method for a polarized OLEDs device based on a two-dimensional elliptical metal nanopillar lattice structured electrode, including the following steps:
S1, substrate pretreatment; cleaning a substrate ultrasonically with a cleaning agent, and then wiping a surface with a cotton ball, removing a solvent on the surface with high-pressure nitrogen and an oven, and then placing a cleaned substrate in an oxygen plasma cleaner for hydrophilic treatment;
S2, preparation of an elliptic metal nanopillar lattice electrode, spin-coating an electron beam resist uniformly on a surface of the substrate, using an electron beam lithography system to prepare a two-dimensional elliptic metal nanopillar lattice structure by an electron beam lithography system, treating the two-dimensional elliptic metal nanopillar lattice structure with developer and fixing solution, depositing a metal film via vacuum thermal evaporation process to remove residual electron beam resist, and obtaining a two-dimensional elliptic metal nanopillar lattice electrode;
S3, placing the two-dimensional elliptical metal nanopillar lattice electrode obtained by S2 in a vacuum evaporation system, and depositing a hole injection layer, a hole transport layer, a luminescent layer, an electron transport layer, and a cathode on the sample by vacuum thermal evaporation to complete a preparation of an entire polarized organic light-emitting device based on the two-dimensional elliptical metal nanopillar lattice structured electrode;
In some embodiments, in S1, the substrate is an ITO-glass substrate, the cleaning agent is acetone, ethanol, and isopropanol, an ultrasonic cleaning time is 10-30 min, and an oxygen plasma treatment time is 3 min.

In some embodiments, in S2, the electron beam resist is polymethyl methacrylate (PMMA), a heating curing temperature is 150 °C, and a time is 3 min.

In some embodiments, in S2, a period of the two-dimensional elliptical metal nanopillar lattice structure prepared by the electron beam lithography system is 310 nm, a short axis radius is fixed at 30 nm, and a long axis radii are 45,60,75,100 nm, respectively.

In some embodiments, in S2, the developer is a mixed solution of methyl isobutyl ketone (MIBK):isopropanol (IPA) at a volume ratio of 1:2, and the fixing solution is isopropanol (IPA) solution; a developing time is 3 min, and a fixing time is 1 min; an acetone solution is used to remove the residual electron beam resist, a time is 20 min.

In some embodiments, in S3, the hole transport layer is one of 4,4′-Cyclohexylidenebis[N,N-bis(4-methylphenyl)aniline] (TAPC), N,N′-diphenyl-N,N′-(1-naphthyl)-1,1′-biphenyl-4,4′-diamine (NPB), and the electron transport layer is one of 1,3,5-tris(1-phenyl-1H-benzimidazol-2-yl)benzene (TPBi), 4,7-diphenyl-1,10-phenanthroline (BPhen), 3,3′-[5′-[3-(3-pyridinyl)phenyl][1,1′:3′,1″-terphenyl]-3,3″-diyl]bispyridine (TmPyPB), the hole injection layer is MoO₃, the cathode is Ca and Ag composite electrode.

In some embodiments, in S3, the luminescent layer is red organic luminescent material and host material, the red organic luminescent material is bis(2-methyldibenzo[F,H]quinoxaline) (acetylacetonate)iridium(III) (Ir(MDQ)₂(acac)), and the host material is 4,4′-bis(N-carbazolyl)-1,1′-biphenyl (CBP) and 1,3-bis(N-carbazolyl)benzene, the red organic luminescent material is doped in the host material with a mass ratio of 8% to prepare an organic phosphorescent luminescent film as the luminescent layer.

The present disclosure also provides a polarized organic light-emitting device based on a two-dimensional elliptical metal nanopillar lattice structured electrode, which is prepared according to the fabrication method for the polarized organic light-emitting device based on a two-dimensional elliptical metal nanopillar lattice structured electrode.

The advantages and beneficial effects of the polarization organic light-emitting device based on the two-dimensional elliptical metal nanopillar lattice structured electrode and its fabrication method are as follows:

The fabrication method for the OLEDs device of the present disclosure uses a two-dimensional elliptical metal nanopillar lattice as the anode, achieving polarization control and improved light extraction efficiency without the need for external accessory optical elements or the limitations of polarized light-emitting materials. To address the problem of non-polarized light emission in traditional OLEDs devices, the cavity mode is directly regulated through the design of a micro/nanostructured metasurface, enabling polarization control of emitted photons and thus realizing polarized light emission for display and lighting applications. Meanwhile, non-radiative mode coupling emission inside the device is excited, which enhances the light extraction efficiency, optimizes device performance, and holds broad application prospects.

The following is a further detailed description of the technical scheme of the present disclosure through drawings and implementation examples.

### BRIEF DESCRIPTION OF THE DRAWINGS

FIG. 1 is a preparation flow chart of the polarized OLEDs device based on the two-dimensional elliptical metal nanopillar lattice structured electrode;

FIG. 2A is a scanning electron microscope image of the lattice structure of two-dimensional elliptical metal nanopillars with different long and short axis ratios in Embodiment 1;

FIG. 2B is a scanning electron microscope image of the lattice structure of two-dimensional elliptical metal nanopillars with different long and short axis ratios in Embodiment 2;

FIG. 3A is a photoluminescence (PL) polarization spectra of Embodiment 1 of the present disclosure;

FIG. 3B is an electroluminescence (EL) polarization spectra of Embodiment 1 of the present disclosure;

FIG. 4A is a PL polarization spectrum of Embodiment 2 of the present disclosure;

FIG. 4B is an EL polarization spectrum of Embodiment 2 of the present disclosure;

FIG. 5A is a current density-voltage relationship diagram of Embodiment 1, Embodiment 2 and the reference OLEDs device;

FIG. 5B is a brightness-current density relationship diagram of Embodiment 1, Embodiment 2 and the reference OLEDs device;

FIG. 5C is a current efficiency-current density relationship diagram of Embodiment 1, Embodiment 2 and the reference OLEDs device.

### DETAILED DESCRIPTION

The following is a further explanation of the technical scheme of the present disclosure through drawings and implementation examples.

Unless otherwise defined, the technical terms or scientific terms used in the present disclosure should be understood by people with general skills in the field to which the present disclosure belongs.

Unless otherwise defined, the reagents, equipment, and other materials used in the present disclosure are conventionally commercially available.

### Embodiment 1

The two-dimensional elliptical metal nanopillar lattice structured electrode is prepared by electron beam lithography, the elliptical metal nanopillar lattice has a period of 310 nm, a short axis radius of 30 nm, and a long axis radius of 60 nm; it is used as the anode of the OLEDs device; the elliptical metal nanopillar lattice electrode selectively amplifies the TM mode, and can effectively extract the photons bound by the plasmon mode on the inner surface of the device, realizing the polarization control of the OLEDs and improving the light extraction ability of the OLEDs device, the electroluminescence of the OLEDs device has a maximum polarization ratio of 2.0 in the red band.

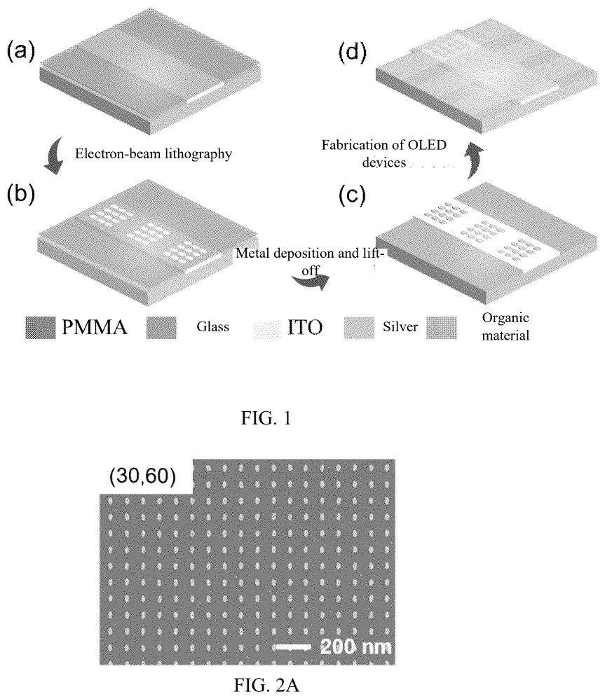

The fabrication method for the polarized OLEDs devices based on the two-dimensional elliptical metal nanopillar lattice structured electrodes, as shown in FIG. 1, includes the following steps:

### (1) Pretreatment of ITO-Glass Substrate

Firstly, the ITO-glass substrate with a size of 2.0 cm×1.8 cm is ultrasonically cleaned with acetone, ethanol, and deionized water for 30 min. Then, the surface is wiped and dried in the order of acetone-ethanol; the drying process includes two processes: nitrogen blow-drying and oven drying, finally, the dry substrate is subjected to oxygen plasma hydrophilic treatment for 3 min.

### (2) Preparation and Morphology Characterization of Two-Dimensional Elliptical Metal Nanopillar Lattice Structured Electrodes

Firstly, the positive electron beam resist polymethyl methacrylate (PMMA) is uniformly spin-coated on the substrate treated by Step (1) at a speed of 6000 rpm, and solidified on a 150 °C hot stage for 3 min. Then, a two-dimensional elliptical lattice with a period of 310 nm is prepared by an electron beam lithography system, where the radius of the short axis is 30 nm and the radius of the long axis is 60 nm. The mixed solution of methyl isobutyl ketone (MIBK):isopropyl alcohol (IPA) with a volume ratio of 1:2 and IPA is used to develop and fix the sample, and the sample is dried with a nitrogen gun; the obtained sample with a two-dimensional elliptical metal nanopillar lattice structure is covered with an organic layer mask and placed in a vacuum evaporation system. The vacuum of the evaporation system is 5×10⁻⁴ Pa, the Ag electrode is evaporated, the thickness is 35 nm, and the deposition rate is 0.85 Å/s; the PMMA without electron beam exposure is removed by a metal lift-off process to obtain an Ag elliptical metal nanopillar lattice electrode.

### (3) Fabrication of Polarized OLEDs Based on Two-Dimensional Elliptical Metal Nanopillar Lattice Structured Electrodes

The sample with a two-dimensional elliptical metal nanopillar lattice structured electrode prepared by Step (2) is placed in a vacuum evaporation system. After the vacuum degree reaches 5×10⁻⁴ Pa, the hole injection layer, hole transport layer, light emitting layer, electron transport layer, and metal cathode are evaporated in turn. The red light emitting layer is 4,4′-bis (N-carbazole)-1,1′-biphenyl (CBP) and 8% wt bis (2-methyldibenzo [F,H] quinoxaline) (acetylacetone) iridium (III) (Ir(MDQ)₂(acac)). The thickness of the light emitting layer is 20 nm, and the deposition rate is 2.0 Å/s. The hole injection layer is MoO₃ with a thickness of 5 nm and a deposition rate of 0.45 Å/s. The hole transport layer and electron transport layer are N,N′-diphenyl-N,N′-(1-naphthyl)-1,1′-biphenyl-4,4′-diamine (NPB) and 1,3,5-tris(1-phenyl-1H-benzimidazol-2-yl)benzene (TPBi), respectively. The thicknesses are 40 nm and 35 nm, and the deposition rate is 1.4 Å/s. The composite cathodes are Ca/Ag with thicknesses of 3 nm and 80 nm, and deposition rates of 0.4 Å/s and 1.2 Å/s, respectively. The preparation flow chart of the device is shown in FIG. 1. The preparation of polarized OLEDs devices based on two-dimensional elliptical metal nanopillar lattice structured electrodes is completed, and then the polarized luminescence spectrum and electroluminescence performance of the device are tested.

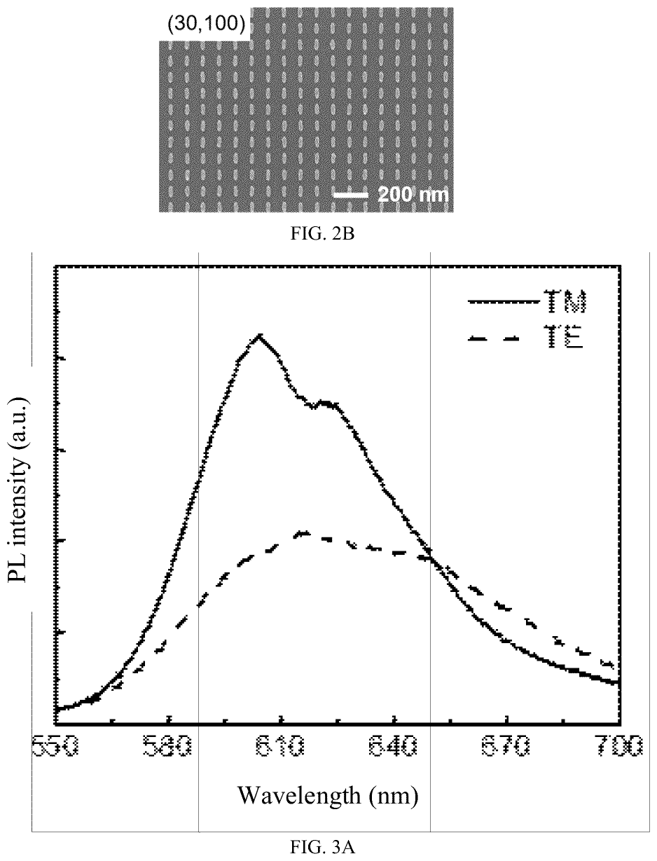

FIG. 2A-2B are the SEM images of the prepared two-dimensional elliptical metal nanopillar lattice structured electrode. It can be seen from the figures that the prepared two-dimensional elliptical metal nanopillar lattice structure has good morphology under the scanning electron microscope, large area uniformity, and good symmetry and consistency.

Then, the excitation light with a wavelength of 400 nm is incident vertically onto the surface of the sample, and a linear polarizer is placed between the photodetector and the sample. The angle-resolved polarized PL spectrum is obtained by rotating the linear polarizer. The maximum and minimum intensities of polarization PL correspond to TM polarization and TE polarization, respectively. Similarly, the polarized EL spectrum of the device is tested. By comparing the intensity of TM and TE polarization EL spectra, the TM/TE polarization ratio of the device is 2.0 at the peak wavelength of 609 nm.

The maximum brightness of the polarized OLEDs device based on the two-dimensional elliptical metal nanopillar lattice structured electrode is increased from 13730 cd/m² to 20180 cd/m² by 46.7%. The two-dimensional elliptical metal nanopillar lattice structured electrode improves the light extraction ability of the OLEDs device.

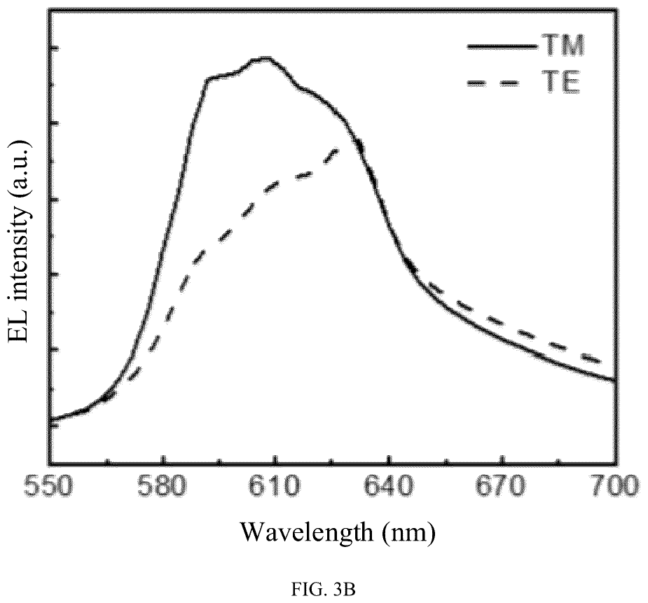

FIG. 3A-3B are the PL and EL polarization spectra of Example 1 of the polarized organic light-emitting device based on the two-dimensional elliptical metal nanopillar lattice structured electrode of the present disclosure. The period of the two-dimensional periodic elliptical lattice is 310 nm, the short axis radius is 30 nm, and the long axis radius is 60 nm.

It can be seen from FIG. 3A-3B that after the introduction of two-dimensional elliptical metal nanopillar lattice electrodes, the PL and EL emission characteristics of OLEDs devices are significantly different in the two polarization modes of transverse magnetic polarization (TM) and transverse electric polarization (TE), respectively, and the PL and EL emission intensities of TM mode are higher than those of TE mode in the corresponding wavelength range. Under the two different excitation modes of PL and EL, the consistent difference regulation of the luminescence characteristics of different polarization modes is carried out, which strongly proves that the elliptical lattice structure has a significant polarization regulation effect on OLEDs devices. The OLEDs device based on the two-dimensional elliptical metal nanopillar lattice electrode with a short axis radius of 30 nm and a long axis radius of 60 nm has a maximum polarization ratio of 2.0 in the red light band.

### Example 2

The two-dimensional elliptical metal nanopillar lattice structured electrode is prepared by electron beam lithography. The elliptical metal nanopillar lattice has a period of 310 nm, a short axis radius of 30 nm, and a long axis radius of 100 nm. It is used as the anode of the OLEDs device. The elliptical metal nanopillar lattice electrode selectively amplifies the transverse magnetic polarization mode, and can effectively extract the photons bound by the plasmon mode on the internal surface of the device, realizing the polarization control of the OLEDs and improving the light extraction ability of the OLEDs device. The electroluminescence of the OLEDs device has a maximum polarization ratio of 3.2 in the red band.

Fabrication of the polarized OLEDs device based on the two-dimensional elliptical metal nanopillar lattice structured electrode, including the following steps:

### (1) Pretreatment of ITO-Glass Substrate

Firstly, the ITO-glass substrate with a size of 2.0 cm×1.8 cm is ultrasonically cleaned with acetone, ethanol, and deionized water for 30 min, then the surface is wiped and dried in the order of acetone-ethanol, the drying process includes two processes: nitrogen blow-drying and oven drying. Finally, the dry substrate is subjected to oxygen plasma hydrophilic treatment for 3 min.

### (2) Preparation and Morphology Characterization of Two-Dimensional Elliptical Metal Nanopillar Lattice Structured Electrodes

Firstly, the positive electron beam resist polymethyl methacrylate (PMMA) is uniformly spin-coated on the substrate treated by Step (1) at a speed of 6000 rpm, and solidified on a 150 °C hot stage for 3 min. After that, a two-dimensional elliptical metal nanopillar array with a period of 310 nm is prepared by an electron beam lithography system, in which the short axis radius is 30 nm, and the long axis radius is 100 nm. Methyl isobutyl ketone (MIBK):isopropanol (IPA) mixed solution and IPA are used to develop and fix the sample, and the sample is dried by a nitrogen gun. The obtained sample with a two-dimensional elliptical metal nanopillar lattice structure is covered with an organic layer mask and placed in a vacuum evaporation system. The vacuum degree of the coating instrument is 5×10⁻⁴ Pa, the Ag electrode is evaporated, the thickness is 35 nm, and the deposition rate is 0.85 Å/s; the PMMA without electron beam exposure is removed by a metal lift-off process to obtain an Ag elliptical metal nanopillar lattice electrode.

### (3) Fabrication of Polarized OLEDs Based on Two-Dimensional Elliptical Metal Nanopillar Lattice Structured Electrodes

The sample with a two-dimensional elliptical metal nanopillar lattice structured electrode prepared in Step (2) is placed in a vacuum evaporation system. After the vacuum degree reaches 5×10⁻⁴ Pa, the hole injection layer, hole transport layer, light emitting layer, electron transport layer, and metal cathode are evaporated in turn. The red light emitting layer is 4,4′-bis (N-carbazole)-1,1′-biphenyl (CBP) and 8% wt bis (2-methyldibenzo [F,H] quinoxaline) (acetylacetone) iridium (III) (Ir (MDQ) 2 (acac)). The thickness of the light emitting layer is 20 nm, and the deposition rate is 2.0 Å/s. The hole injection layer is MoO₃ with a thickness of 5 nm and a deposition rate of 0.45 Å/s. The hole transport layer and electron transport layer are N,N′-diphenyl-N,N′-(1-naphthyl)-1,1′-biphenyl-4,4′-diamine (NPB) and 1,3,5-tris(1-phenyl-1H-benzimidazol-2-yl)benzene (TPBi), respectively. The thickness is 40 nm and 35 nm, and the deposition rate is 1.4 Å/s; the composite cathodes are Ca/Ag with thicknesses of 3 nm and 80 nm, and deposition rates of 0.4 Å/s and 1.2 Å/s, respectively. The preparation of the polarized OLEDs devices based on the two-dimensional elliptical metal nanopillar lattice structured electrodes is completed.

Then, the excitation light with a wavelength of 400 nm is incident vertically onto the surface of the sample, and a linear polarizer is placed between the photodetector and the sample. The angle-resolved polarized PL spectrum is obtained by rotating the linear polarizer. The maximum and minimum intensities of polarization PL correspond to TM polarization and TE polarization, respectively. Similarly, the polarized EL spectrum of the device was tested. By comparing the intensity of TM and TE polarization EL spectra, the TM/TE polarization ratio of the device is 3.2 at the peak wavelength of 609 nm.

The maximum brightness of the polarized OLEDs device based on the two-dimensional elliptical metal nanopillar lattice structured electrode is increased from 13730 cd/m² to 21120 cd/m² by 53.8%, the two-dimensional elliptical metal nanopillar lattice structured electrode improves the light extraction ability of the OLEDs device.

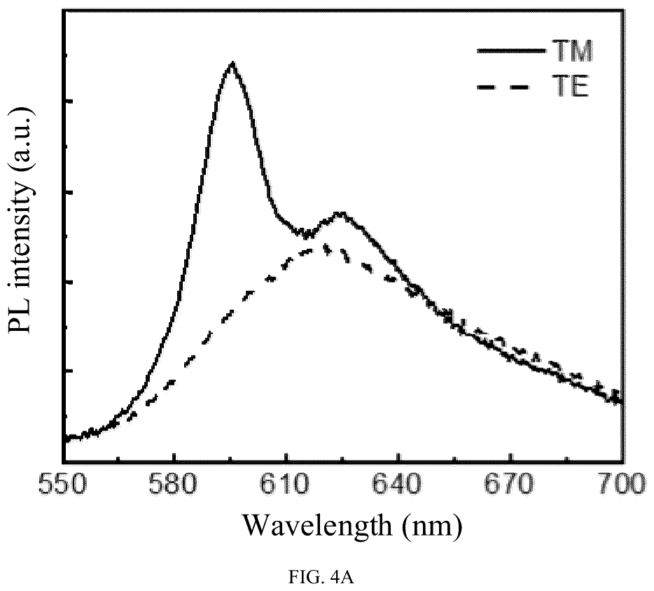

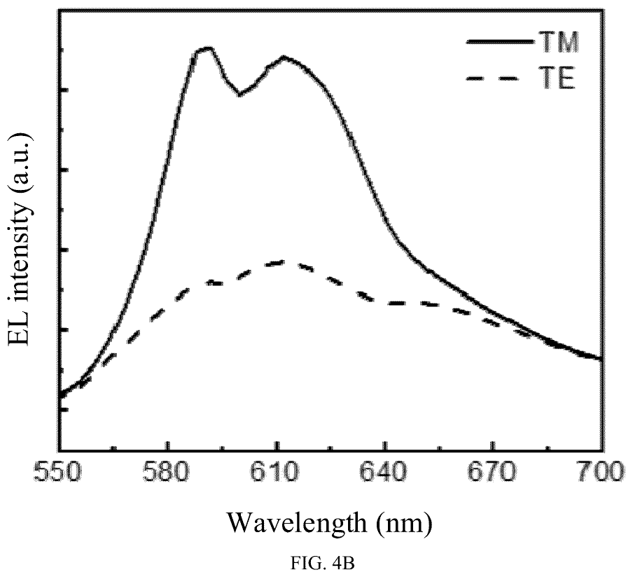

FIG. 4 is the PL and EL polarization spectra of the polarization OLEDs device embodiment 2 based on the two-dimensional elliptical metal nanopillar lattice structured electrode. The period of the two-dimensional elliptical metal nanopillar lattice is 310 nm, the short axis radius is 30 nm, and the long axis radius is 100 nm. The highest polarization ratio of OLEDs with two-dimensional elliptical metal nanopillar lattice electrodes in the red band is 3.2.

From FIG. 3A-3B and FIG. 4A-4B, it can be seen that with the increase of the degree of asymmetry of the two-dimensional elliptical metal nanopillar array, the polarization ratio of the OLEDs device increases significantly with the increase of the ratio of the long axis to the short axis of the structure, which proves the customizable polarization control of the elliptical metal nanopillar array on the OLEDs.

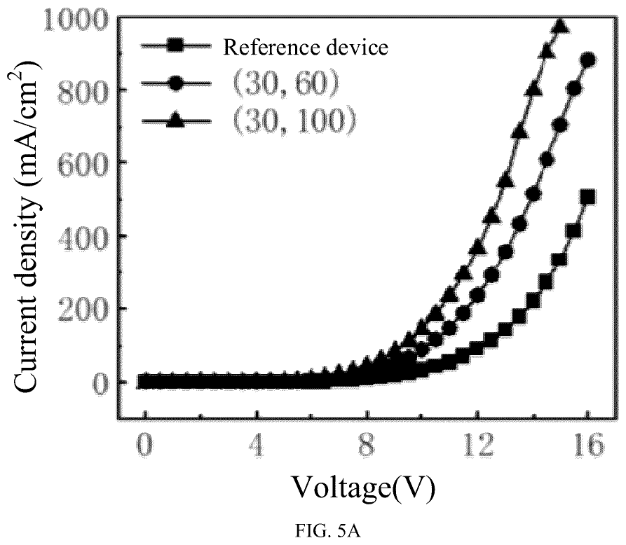

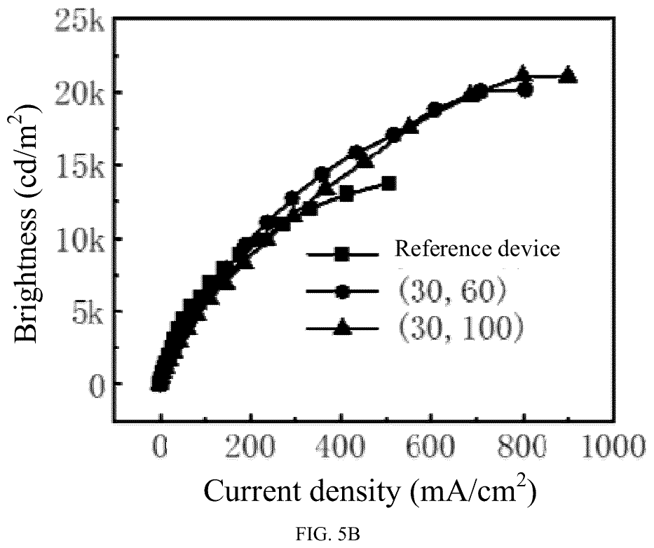

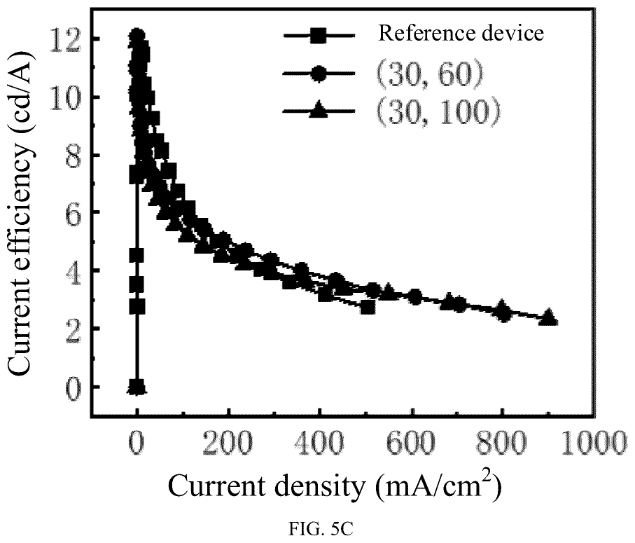

It can be seen from FIG. 5A-5C that the maximum brightness of the OLEDs device based on the two-dimensional elliptical metal nanopillar lattice electrode with a short axis radius of 30 nm and a long axis radius of 60 nm is 20050 cd/m², which is 46% higher than the maximum brightness of the reference device of 13730 cd/m². By balancing photon extraction and charge transport, the maximum current efficiency of OLEDs based on the two-dimensional elliptical metal nanopillar lattice structure is increased to 12.07 cd/A compared with 11.68 cd/A of planar devices. The maximum brightness of the OLEDs device based on the two-dimensional elliptical metal nanopillar lattice electrode with a short axis radius of 30 nm and a long axis radius of 100 nm is 21120 cd/m², which is 53% higher than that of the reference device, and the maximum current efficiency is 11.85 cd/A.

### Example 3

Fabrication of polarized OLEDs devices based on the two-dimensional elliptical metal nanopillar lattice structured electrodes, including the following steps:

### (1) Pretreatment of ITO-Glass Substrate

Firstly, the ITO-glass substrate with a size of 2.0 cm×1.8 cm is ultrasonically cleaned with acetone, ethanol, and deionized water for 30 min, then the surface is wiped and dried in the order of acetone-ethanol. The drying process included two processes: nitrogen blow-drying and oven drying. Finally, the dry substrate is subjected to oxygen plasma hydrophilic treatment for 3 min.

### (2) Preparation and Morphology Characterization of the Two-Dimensional Elliptical Metal Nanopillar Lattice Structured Electrodes

Firstly, the positive electron beam resist polymethyl methacrylate (PMMA) is uniformly spin-coated on the substrate treated by Step (1) at a speed of 6000 rpm, and solidified on a 150 °C hot stage for 3 min. After that, a two-dimensional elliptical metal nanopillar array with a period of 310 nm is prepared by an electron beam lithography system, in which the short axis radius is 30 nm, and the long axis radius is 100 nm. The mixed solution of methyl isobutyl ketone (MIBK):isopropanol (IPA) with a volume ratio of 1:2 and IPA is used to develop and fix the sample, and the sample is dried with a nitrogen gun. The obtained sample with a two-dimensional elliptical metal nanopillar lattice structure is covered with an organic layer mask and placed in a vacuum evaporation system. The vacuum of the coating instrument is 5×10⁻⁴ Pa, the Ag electrode is evaporated, the thickness is 35 nm, and the deposition rate is 0.85 Å/s; the PMMA without electron beam exposure is removed by a metal lift-off process to obtain an Ag elliptical metal nanopillar lattice electrode.

### (3) Fabrication of Polarized OLEDs Based on Two-Dimensional Elliptical Metal Nanopillar Lattice Structured Electrodes

The sample with the two-dimensional elliptic metal nanopillar lattice structured electrode prepared by Step (2) is put into the evaporation system. When the vacuum degree reaches 5×10⁻⁴ Pa, the hole injection layer, hole transport layer, light emitting layer, electron transport layer, and metal cathode are successively evaporated. The red light emitting layer is 1,3-bis (N-carbazolyl) benzene and 8% wt bis (2-methyldibenzo [F,H] quinoxaline) (acetylacetone) iridium (III) (Ir(MDQ)₂(acac)), the thickness of the light emitting layer is 20 nm, and the deposition rate is 2.0 Å/s; the hole injection layer is MoO₃ with a thickness of 5 nm and a deposition rate of 0.45 Å/s. The hole transport layer and electron transport layer are 4,4′-cyclohexyldi [N,N-bis (4-methylphenyl) aniline] (TAPC) and 4,7-diphenyl-1,10-phenanthroline (BPhen), respectively. The thickness of the hole transport layer and electron transport layer are 40 nm and 35 nm, respectively; the deposition rate is 1.4 Å/s, the composite cathodes are Ca/Ag with thicknesses of 3 nm and 80 nm, and deposition rates of 0.4 Å/s and 1.2 Å/s, respectively. The preparation of polarized OLEDs devices based on the two-dimensional elliptical lattice structured electrode is completed.

Therefore, the present disclosure adopts the polarized organic light-emitting device based on the two-dimensional elliptical metal nanopillar lattice structured electrode and the fabrication method thereof. By integrating the two-dimensional elliptical metal nanopillar lattice structure with ITO, the composite electrode is designed as the OLEDs anode, and the polarization control of the OLEDs device is realized, and the light extraction efficiency of the OLEDs device is improved. The cavity mode of the OLEDs device is directly regulated by the design of the micro-nano structure metasurface, so as to realize the polarized light emission of the OLEDs device in the fields of display and lighting without the external optical components of the accessory and without the limitation of the polarized light material. The two-dimensional elliptical metal nanopillar lattice structure excites the internal non-radiative mode coupling out of the device to achieve device light extraction efficiency improvement and device performance optimization.

Finally, it should be explained that the above embodiments are only used to explain the technical scheme of the present disclosure rather than restrict it. Although the present disclosure is described in detail with reference to the best embodiment, the ordinary technical personnel in this field should understand that they can still modify or replace the technical scheme of the present disclosure, and these modifications or equivalent substitutions cannot make the modified technical scheme out of the spirit and scope of the technical scheme of the present disclosure.

What is claimed is:

1. A fabrication method for a polarized organic light-emitting device based on a two-dimensional elliptical metal nanopillar lattice structured electrode, it comprises the following steps:
S1, substrate pretreatment; cleaning a substrate ultrasonically with a cleaning agent, and then wiping a surface with a cotton ball, removing a solvent on the surface with high-pressure nitrogen and an oven, and then placing a cleaned substrate in an oxygen plasma cleaner for hydrophilic treatment;
S2, preparation of an elliptic metal nanopillar lattice electrode, spin-coating an electron beam resist uniformly on a surface of the substrate, using an electron beam lithography system to prepare a two-dimensional elliptic metal nanopillar lattice structure by an electron beam lithography system, treating the two-dimensional elliptic metal nanopillar lattice structure with developer and fixing solution, depositing a metal film via vacuum thermal evaporation process to remove residual electron beam resist, and obtaining a two-dimensional elliptic metal nanopillar lattice electrode; and
S3, placing the two-dimensional elliptical metal nanopillar lattice electrode obtained by S2 in a vacuum evaporation system, and depositing a hole injection layer, a hole transport layer, a luminescent layer, an electron transport layer, and a cathode on the sample by vacuum thermal evaporation to complete a preparation of an entire polarized organic light-emitting device based on the two-dimensional elliptical metal nanopillar lattice structured electrode.

2. The fabrication method for the polarized organic light-emitting device based on the two-dimensional elliptical metal nanopillar lattice structured electrode according to claim 1, wherein in S1, the substrate is an ITO-glass substrate, the cleaning agent is acetone, ethanol, and isopropanol, an ultrasonic cleaning time is 10-30 min, and an oxygen plasma treatment time is 3 min.

3. The fabrication method for the polarized organic light-emitting device based on the two-dimensional elliptical metal nanopillar lattice structured electrode according to claim 1, wherein in S2, the electron beam resist is polymethyl methacrylate, a heating curing temperature is 150 °C, and a time is 3 min.

4. The fabrication method for the polarized organic light-emitting device based on the two-dimensional elliptical metal nanopillar lattice structured electrode according to claim 1, wherein in S2, a period of the two-dimensional elliptical metal nanopillar lattice structure prepared by the electron beam lithography system is 310 nm, a short axis radius is fixed at 30 nm, and long axis radii are 45,60,75,100 nm, respectively.

5. The fabrication method for the polarized organic light-emitting device based on the two-dimensional elliptical metal nanopillar lattice structured electrode according to claim 1, wherein in S2, the developer is a mixed solution of methyl isobutyl ketone:isopropanol at a volume ratio of 1:2, and the fixing solution is isopropanol solution; a developing time is 3 min, and a fixing time is 1 min; an acetone solution is used to remove the residual electron beam resist, a time is 20 min.

6. The fabrication method for the polarized organic light-emitting device based on the two-dimensional elliptical metal nanopillar lattice structured electrode according to claim 1, wherein in S3, the hole transport layer is one of 4,4′-Cyclohexylidenebis[N,N-bis(4-methylphenyl)aniline], N,N′-diphenyl-N,N′-(1-naphthyl)-1,1′-biphenyl-4,4′-diamine, and the electron transport layer is one of 1,3,5-tris(1-phenyl-1H-benzimidazol-2-yl)benzene, 4,7-diphenyl-1,10-phenanthroline, 3,3′-[5′-[3-(3-pyridinyl)phenyl][1,1′:3′,1″-terphenyl]-3,3″-diyl]bispyridine, the hole injection layer is MoO₃, the cathode is Ca and Ag composite electrode.

7. The fabrication method for the polarized organic light-emitting device based on the two-dimensional elliptical metal nanopillar lattice structured electrode according to claim 1, wherein in S3, the luminescent layer is red organic luminescent material and host material, the red organic luminescent material is bis(2-methyldibenzo[F,H]quinoxaline) (acetylacetonate)iridium(III), and the host material is 4,4′-bis(N-carbazolyl)-1,1′-biphenyl and 1,3-bis(N-carbazolyl)benzene, the red organic luminescent material is doped in the host material with a mass ratio of 8% to prepare an organic phosphorescent luminescent film as the luminescent layer.

8. A polarized organic light-emitting device based on a two-dimensional elliptical metal nanopillar lattice structured electrode, wherein the device is prepared according to the fabrication method according to claim 1.
